(19) United States
(12) Patent Application Publication
(10) Pub. No.: US 2026/0101743 A1
(43) Pub. Date: Apr. 9, 2026

(54) BONDED DEVICE HAVING SPLIT BONDING LAYER AND METHODS OF FORMATION

(71) Applicant: Applied Materials, Inc., Santa Clara, CA (US)

(72) Inventors: Siddarth Krishnan, San Jose, CA (US); Michael Patrick Chudzik, Mountain View, CA (US)

(73) Assignee: Applied Materials, Inc., Santa Clara, CA (US)

(21) Appl. No.: 18/883,716

(22) Filed: Sep. 12, 2024

(51) Int. Cl. H01L 23/00; H01L 23/528

(52) U.S. Cl. CPC H10W 20/427; H10W 72/01338; H10W 72/01365; H10W 72/07331; H10W 72/327; H10W 72/353; H10W 90/734

(57) ABSTRACT

A method of forming a bonded device. The method may include providing a carrier substrate, forming, on a first surface of the carrier substrate, a first bonding layer for bonding to a device substrate, and annealing the first bonding layer at a temperature of greater than 600° C.

### FIELD

The present embodiments relate to semiconductor devices and in particular devices based upon bonded wafers.

### BACKGROUND

Devices such as integrated circuits, memory devices, and logic devices may be fabricated on a substrate such as a semiconductor wafer by a combination of deposition processes, etching, ion implantation, annealing, and other processes. Present day devices may are based upon various structural and process innovations including three dimensional transistors, which innovations are employed in order to improve device performance, facilitate device scaling to smaller dimensions, and so forth.

Other recent innovations include fabricating devices that use the bonding of two different semiconductor wafers to one another, such as silicon wafers. One such example of bonded wafer technology is termed backside power delivery network (BPSDN) technology. This technology entails a device architecture where power supply lines are routed to the backside of a semiconductor chip or integrated circuit, instead of routing the power supply lines on the frontside of the chip. This technique then facilitates improved device density as well as increased power and performance.

One issue with such bonded devices is that the thermal conductivity of the bonding layer, such as SiO₂, may be relatively lower, such that heat transfer to the carrier wafer may be unduly low. When the final bonded device is operated, heat that is generated in the device wafer will be conducted from the device wafer and into the carrier wafer, where the heat may be dissipated to an external component. When the thermal conductivity of the bonding layer is insufficient, the heat may thus unduly build up in the device wafer due to poor heat transfer to the carrier wafer, and may affect device performance, robustness, among other factors.

In principle, such bonded devices may employ bonding layers having relatively higher thermal conductivity. As an example, AlN was contemplated for use as a bonding layer. After deposition of AlN on a device wafer, the device wafer is joined to the carrier wafer. In order to avoid deleterious effects on the devices or circuits of the device wafer caused by excessive temperature, the formation of the AlN layer on the device layer is limited to relatively lower temperatures, such as ˜400° C. or below. At these formation temperatures, the thermal conductivity of the resulting AlN layer may still be relatively low. Thus, current approaches for forming bonded devices including a carrier wafer, device wafer, and bonding layer may be less than ideal.

With respect to these and other considerations the present embodiments are provided.

### BRIEF SUMMARY

In one embodiment, a method of forming a bonded device is provided. The method may include providing a carrier substrate, forming, on a first surface of the carrier substrate, a first bonding layer for bonding to a device substrate, and annealing the first bonding layer at a temperature of greater than 600° C.

In another embodiment, a bonded device is provided. The bonded device may include a carrier substrate, a device substrate, and a first bonding layer at an inner surface of the carrier substrate, and a second bonding layer at an inner surface of the device substrate, where the second bonding layer is bonded to the first bonding layer. As such, the first bonding layer and the second bonding layer may comprise a same material, and an average grain size of the first bonding layer may be greater than an average grain size of the second bonding layer.

### BRIEF DESCRIPTION OF THE DRAWING

FIG. 1A depicts a cross-sectional view of a bonded device, according to embodiments of the disclosure;

FIG. 1B depicts details of a device substrate and bonding layer of a bonded device, according to embodiments of the disclosure;

FIG. 1C presents a cross-section of a variant of the device of FIG. 1A;

FIG. 2 is a composite diagram illustrating a cross-section of components of a bonded device and the process flow for assembling the bonded device, according to embodiments of the disclosure;

FIG. 3 is a graph illustrating a comparison of thermal conductivity for various materials;

FIG. 4 is a graph depicting device leakage as a function of post-deposition annealing conditions for devices coated with an AlN thermal conduction layer;

FIG. 5 presents an exemplary process flow, according to some embodiments of the disclosure; and

FIG. 6 presents another exemplary process flow, according to further embodiments of the disclosure.

### DETAILED DESCRIPTION

The present embodiments will now be described more fully hereinafter with reference to the accompanying drawings, where some embodiments are shown. The subject matter of the present disclosure may be embodied in many different forms and are not to be construed as limited to the embodiments set forth herein. Instead, these embodiments are provided so this disclosure will be thorough and complete, and will fully convey the scope of the subject matter to those skilled in the art. In the drawings, like numbers refer to like elements throughout.

The embodiments described herein relate to techniques and structures for improved performance of bonded devices. Non-limiting examples of a bonded device according to the present embodiments include a BPSDN device having a semiconductor carrier substrate that is bonded to a semiconductor device substrate. Another example is a system on a chip (SOC) type device where one or more semiconductor device substrates (chips) is bonded to a carrier substrate, which substrate may also be a semiconductor material, such as silicon.

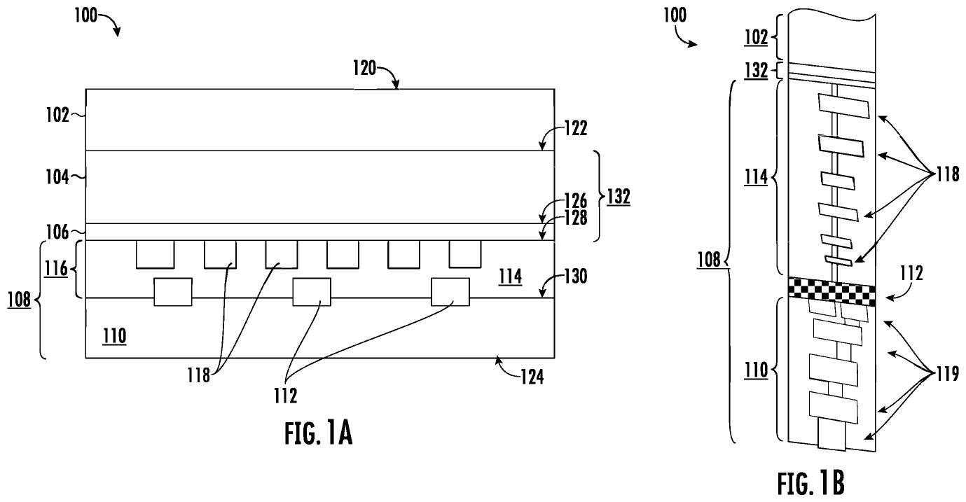

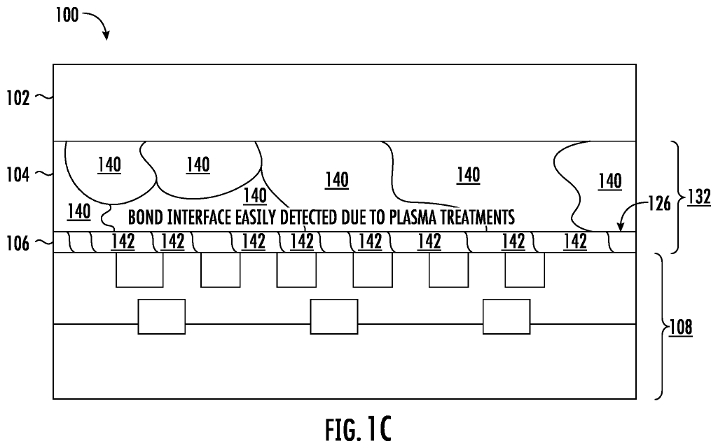

FIG. 1A depicts a cross-sectional view of a bonded device 100, according to embodiments of the disclosure. FIG. 1B depicts details of a device substrate and bonding layer that form parts of a bonded device, according to embodiments of the disclosure. Turning in particular to FIG. 1A, the bonded device 100 includes a carrier substrate 102 that is defined by an outer surface 120 and an inner surface 122. The carrier substrate 102 may be a semiconductor wafer or a semiconductor chip according to various embodiments. The bonded device 100 further includes a first bonding layer 104, having an upper surface that is affixed to the inner surface 122. The bonded device 100 includes a second bonding layer 106, affixed at an internal interface 126 to the first bonding layer 104. In some examples, the internal interface 126 may represent the original lower surface of the first bonding layer 104, while in other examples the internal interface 126 may represent an interface region that may encompass the original lower surface of the first bonding layer 104. As detailed herein below, the first bonding layer 104 and the second bonding layer 106 are formed separately and are joined together to produce a final layer that may be termed a thermal conduction layer 132.

The bonded device 100 further includes a device substrate 108, affixed to the second bonding layer 106. In some embodiments, the device substrate 108 may represent a semiconductor wafer, or one or more semiconductor chips, including logic circuits, memories, and so forth. For purposes of simplicity of illustration the device substrate 108 is shown as having a frontside region 116 and a backside region 110. The frontside region 116 may include semiconductor devices 112 as well conductive structures such as wiring 118. The wiring 118 may be embedded in an insulator material 114. As shown, the device substrate 108 is arranged so that the second bonding layer 106 is disposed directly over the front side region 116.

Turning also to FIG. 1B, in some embodiments, the device substrate 108 may be based upon so-called BSPDN technology, discussed previously. Briefly, the backside power delivery network architecture places a backside wiring network, such as backside wiring network 119, ‘below’ the device level, as represented by semiconductor devices 112, in order to route power circuitry toward the backside of the device substrate 108, meaning the lower surface 124 of device substrate 108. Thus, in the embodiments of a BPSDN device, the wiring 118 in the frontside region 116 may represent signal wiring.

In accordance with various embodiments of the disclosure, the thermal conduction layer 132 provides a thermal conduction path from device substrate 108 to carrier substrate 102 in order to transfer heat away from the device substrate 108, where devices and circuitry may generate substantial levels of heat during operation. Thus, during operation, the semiconductor devices 112 and related circuitry and components may generate heat that may flow to the carrier substrate 102 by way of the thermal conduction layer 132.

In various embodiments of the disclosure, the first bonding layer 104 and the second bonding layer 106 may be formed of the same material, such as a high thermal conduction material which material may be a dielectric material. Suitable non-limiting examples of a high thermal conduction material include AlN, AlON, bilayers of AlN/AlO, AlN/SiO, hexagonal-BN, crystalline diamond, among other materials. Thus, the thermal conduction layer 132 provides a relatively higher thermal conduction path for dissipating heat from the device substrate 108.

As suggested in FIG. 1A, and in keeping with various embodiments of the disclosure, the first bonding layer 104 may have a first thickness, where the second bonding layer 106 has a second thickness, less than the first thickness. In some non-limiting examples, the first thickness is between 30 and 100 nm, and the second thickness is between 10 nm and 20 nm. Thus, in some examples, the first bonding layer 104 may extend over 90% of the thickness of the thermal conduction layer 132. As previously noted, in the present embodiments, the first bonding layer 104 may be processed separately from the second bonding layer 106, and therefore may be treated in a manner to provide advantageous properties to the first bonding layer, including superior thermal conductivity. Because the first bonding layer 104 may constitute the large portion of the thickness of the thermal conduction layer 132, the overall thermal properties of the thermal conduction layer may imparted based primarily upon the properties of the first bonding layer 104.

To further illustrate this point FIG. 1C presents a cross-section of a variant of the device 100 of FIG. 1A. In this example, the thermal conduction layer 132 includes the first bonding layer 104 and the second bonding layer 106, discussed previously. In this example, the microstructure of the thermal conduction layer 132 is depicted in more detail. In particular, the first bonding layer 104 and the second bonding layer 106 may be characterized by a polycrystalline microstructure. For one example, the first bonding layer 104 and the second bonding layer 106 may be formed of a polycrystalline AlN material. As suggested by FIG. 1C, the first bonding layer 104 may be characterized by an assemblage of crystallites 140, while the second bonding layer 106 is characterized by an assemblage of crystallites 142. In this example, the grain size of the crystallites 140 is substantially larger than the grain size of the crystallites 142. In some non-limiting embodiments, the grain size of crystallites 140 and crystallites 142 may be on the order of tens of nm, such as 10 nm or more. According to some non-limiting embodiments, the grain size of crystallites 140 may be 10% to 100% larger than the grain size of crystallites 142. This difference in grain size of the crystallites in the two different bonding layers of thermal conduction layer 132 may be a consequence of different treatments imparted to the first bonding layer 104 on the one hand, and the second bonding layer 106, on the other hand. One result of this microstructure may be where the thermal conduction layer 132 exhibits less overall defects in comparison to a thermal conduction layer where the relative thickness of the second bonding layer 106 were greater, or in the case where the thermal conduction layer were entirely composed of the second bonding layer 106. Concomitant with the lower defectivity produced by the microstructure dominated by the large crystallites (crystallites 140) may be a relatively higher thermal conductivity of the thermal conduction layer 132.

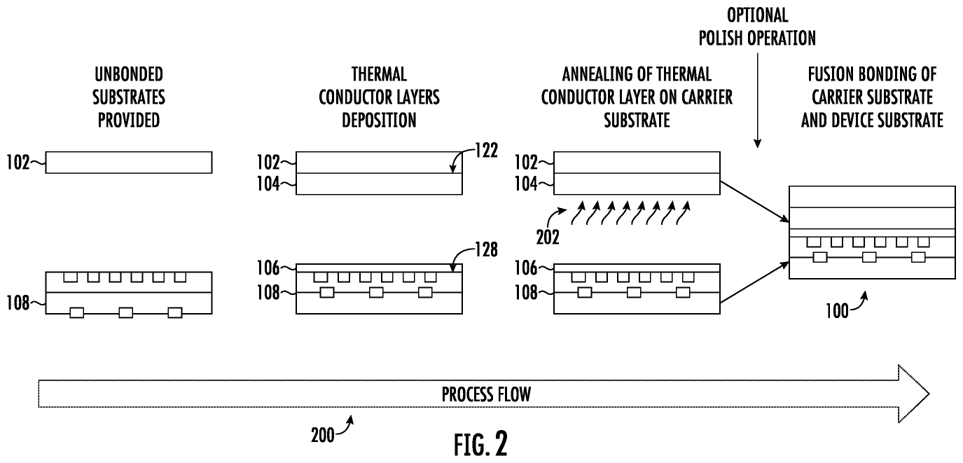

In order to achieve the structure of the aforementioned embodiments of FIGS. 1A-1C, FIG. 2 provides a composite diagram illustrating a cross-section of components of a bonded device at various stages, and the process flow for assembling the bonded device, according to embodiments of the disclosure. A process flow 200 is depicted, where the assembly of the device 100 generally flows from left to right in the figure. In one instance, illustrated at the far left of the figure, two different unbonded substrates are provide, indicated as carrier substrate 102, and device substrate 108, where examples of the features of these substrates have been detailed previously.

In a subsequent set of operations material that acts as thermal conduction layers is deposited upon the carrier substrate 102 and on the device substrate 108. Note that these thermal conduction layers may correspond to the first bonding layer 104 and the second bonding layer 106. Note that the deposition of the thermal conduction layers will take place at the surfaces indicated in FIG. 2, which surfaces have been discussed previously. In some embodiments of the disclosure, the deposition of the first bonding layer 104 and the second bonding layer 106 constitutes deposition of AlN. In some embodiments, the deposition of the first bonding layer 104 and the second bonding layer 106 may take place at a suitable substrate temperature that may or may not differ for the two different depositions. In some embodiments, the deposition of the first bonding layer 104 and the second bonding layer 106 may be performed by physical vapor deposition, such as by sputtering. An example of a suitable substrate temperature for depositing AlN may be 300° C., 350° C., 400° C., or 425° C., according to some non-limiting embodiments. Note that in order to deposit an AlN layer while preserving proper functioning of the device substrate 108, the deposition temperature for second bonding layer 108 may be set at 425 C or less, so as not to degrade components on the device substrate 108. At this stage, in one example, deposition of the first bonding layer 104 may take place separately from deposition of the second bonding layer 106, so that the thickness of the first bonding layer 104 may differ from the thickness of the second bonding layer 106. In some examples, the thickness of the first bonding layer 104 may be substantially greater than the thickness of the second bonding layer 106.

In a further operation, the first bonding layer 104 may be separately subjected to post deposition annealing by an annealing process 202, such as furnace annealing, rapid thermal annealing (RTA), laser annealing, and so forth. The annealing process may be designed so as to improve the properties of the first bonding layer 104 to meet device requirements. In particular, according to the present embodiments, the exact process flow for forming and the design of the thermal conduction layer 132 may be set to establish suitable thermal conduction properties for a bonded system, such as a BSPDN device. To accomplish these properties, the first bonding layer 104 may be separately processed subjecting just the first bonding layer 104 to the post-deposition annealing process, while not subjecting the second bonding layer 106 to the annealing process.

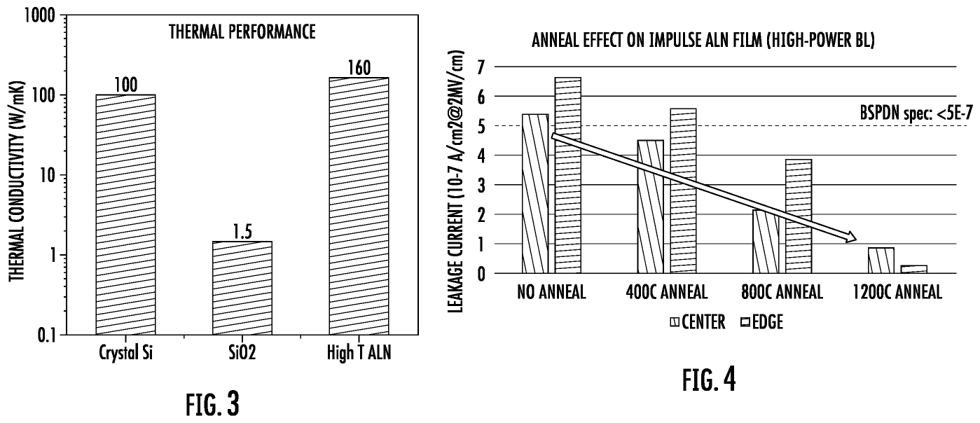

After the completion of the annealing process, the thermal conduction properties of the first bonding layer 104 may be improved, by causing the properties to approach the ideal properties of a thermal conduction layer, such as AlN. By way of reference, FIG. 3 is a graph illustrating a comparison of thermal conductivity for various materials. As shown in FIG. 3, monocrystalline silicon exhibits a thermal conductivity (K) of 100 W/mK, while SiO₂ exhibits a thermal conductivity of just 1.5 W/mK. Thus, a bonding system based upon a silicon carrier substrate with a SiO₂ bonding layer may suffer in terms of thermal conduction, due to the relatively low value of K for SiO₂. FIG. 3A also shows that high temperature AlN layers may exhibit a thermal conductivity as high as 160 W/mK. Thus, in the embodiments where first bonding layer 104 is AlN, the annealing of the AlN may be performed so as to impart suitable thermal properties into the first bonding layer 104 after completion. Because the carrier substrate 102 may include no devices, and may be just a silicon wafer, the annealing temperature for annealing the first bonding layer 104 need not be limited to temperature range that preserves device performance.

To illustrate the effect of post deposition annealing on improving properties of AlN layers, FIG. 4 is a graph depicting device leakage as a function of post-deposition annealing conditions for devices coated with an AlN thermal conduction layer. In this example, a series of samples were prepared by depositing AlN layers on special test substrates that include devices for measuring electrical current leakage. The relative amount of leakage current is directly related to the quality of the AlN layer. As shown in FIG. 4, for AlN layers that are deposited on the test substrate without post-deposition annealing, the leakage current is above 5×10⁷ A/cm² at a field of 2 MV/cm. This value may be considered to be a threshold value not to be exceeded for a particular BSPDN application. After being subjected to a 400° C. post-deposition anneal, the leakage current reduces slightly, but remains near or above 5×10⁷ A/cm². After an 800° C. post-deposition anneal, the leakage current reduces substantially and is well below the threshold value. After a 1200° C. post-deposition anneal, the leakage current is below 1×10⁻⁷ A/cm². Thus, the quality of the AlN layer, and the resulting reduction in leakage, is greatly enhanced by post deposition annealing above 400° C.

Thus, a suitable temperature for post deposition annealing of the first bonding layer 104 formed from AlN may be 600° C., 800° C., 1000° C., or 1200° C., according to some non-limiting embodiments. At such annealing temperatures, the thermal conductivity of the first bonding layer may be improved, and may approach the thermal conductivity as represented by the data of FIG. 3A.

Returning to FIG. 2, in a subsequent operation, the carrier substrate 102 may be joined to the device substrate 108 by placing the first bonding layer 104 in contact with the second bonding layer 106, and conducting a fusion bonding process to affix the first bonding layer 104 to the second bonding layer 106. The fusion bonding process may entail performing a plasma treatment on both substrates (wafers) to be bonded (examples of suitable plasma gases: O, N, Ar), then a hydroxylation process followed by wafer-to-wafer alignment and placement of top wafer onto bottom wafer. After placement, a given wafer pair is annealed in a furnace to form a permanent bond between wafers, with the furnace annealing temperature maintained at a temperature compatible with device tolerance, such as a temperature <425° C. for the specific BSPDN application.

Note that in one variant of the process flow 200, after the annealing of the first bonding layer 104, and before the joining of the carrier substrate and device substrate, an optional polishing operation, such as chemical-mechanical polishing, may be applied to the exposed surfaces of the first bonding layer 104 and the second bonding layer 106, in order to better prepare such surfaces for the subsequent bonding operation.

In the aforementioned embodiments, examples are provided where a carrier substrate, such as a semiconductor wafer is bonded to a device substrate, where the device substrate is also a semiconductor wafer. In additional embodiments of the disclosure, instead of wafer-to-wafer bonding, a substrate, such as a semiconductor wafer, may be bonded to a semiconductor die, such as a single device chip, using a first bonding layer disposed on the semiconductor wafer, and a second bonding layer disposed on the semiconductor die. Thus, in these latter embodiments, the device substrate may represent a semiconductor die rather than a full wafer.

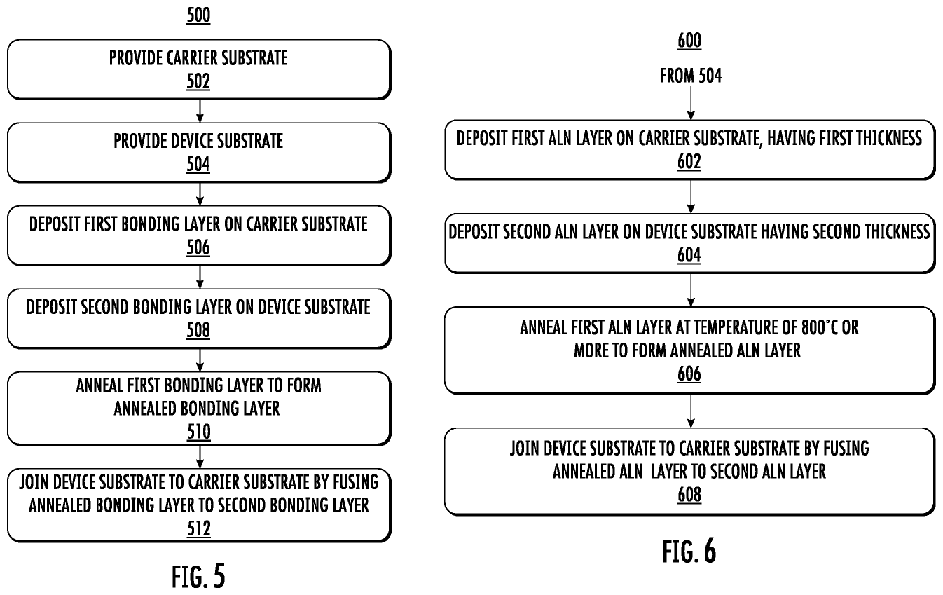

FIG. 5 presents an exemplary process flow 500, according to some embodiments of the disclosure.

At block 502 a carrier substrate is provided. The carrier substrate may be in one example a monocrystalline semiconductor substrate, such as a silicon wafer.

At block 504, a device substrate is provided. The device substrate may include at least one device, such as a semiconductor device, a circuit, and so forth. The device substrate may be based upon a semiconductor wafer such as monocrystalline silicon. In particular embodiments, the device substrate may be based upon BSPDN architecture, including backside wiring.

At block 506, a first bonding layer is deposited on a surface of the carrier substrate. In some embodiments, the first bonding layer may be a thermally conductive layer such as AlN. The first bonding layer may be deposited by a physical vapor deposition (PVD) process, such as sputtering. The substrate temperature for depositing the first bonding layer may be a suitable temperature, such as 300° C. to 500° C.

At block 508, a second bonding layer is deposited on a surface of the device substrate. In one example of a BSPDN device, the second bonding layer may be deposited on the ‘front side’ of the device wafer, meaning the surface where signaling wiring and associated dielectric layer(s) are located. In some embodiments, the second bonding layer may be deposited by PVD, and may be formed of a same material as the material of the first bonding layer. According to some embodiments, the substrate temperature for depositing the second bonding layer may be maintained at a suitable temperature below 425° C., such as 400° C., 350° C., 300° C., and so forth. Suitable non-limiting examples of a high thermal conduction material for use as the first bonding layer as well as the second bonding layer include AlN, AlON, bilayers of AlN/AlO, AlN/SiO, hexagonal-BN, and crystalline diamond. Note that the material of the first bonding layer may differ from the material of the second bonding layer, to the extent that the two bonding layers are compatible with one another to form a suitable bond therebetween.

At block 510 the first bonding layer is annealed after deposition to form an annealed bonding layer. In some non-limiting examples, where the first bonding layer is AlN, the annealing may take place at a substrate temperature of 600° C., 800° C., 1000° C., or 1200° C. In particular embodiments, the second bonding layer may remain unannealed after deposition.

In some embodiments, the operations of block 506 and block 508 may be performed in a common tool. In other embodiments, the operations of block 506, block 508, and block 510 may be performed in a common tool.

At block 512, the carrier substrate is joined to the device substrate by bringing the two substrates together and fusing the annealed bonding layer to the second bonding layer of the device substrate. The fusion bonding process may entail performing a plasma treatment of both substrates to be joined, followed by other processing as detailed herein above. In particular, the fusing of the two substrates may be completed by a furnace annealing the of two substrates, with the furnace annealing temperature maintained at a temperature compatible with device tolerance, such as a temperature <425° C. for the specific BSPDN application.

FIG. 6 presents another exemplary process flow 600, according to further embodiments of the disclosure. The flow begins at block 502 and block 504 and proceeds to block 602. At block 602, a first AlN layer is deposited on the carrier substrate, such as a silicon wafer. The first AlN layer may be deposited by physical vapor deposition in some embodiments and may be deposited according to a first thickness, which thickness may be predetermined.

At block 604, a second AlN layer is deposited on the device substrate. The second AlN layer may also be deposited by physical vapor deposition and may be deposited to have a second thickness. The second thickness may be the same as the first thickness, less than the first thickness or greater than the first thickness, according to different embodiments. In some non-limiting examples, the first thickness may range between 30 nm to 100 nm, while the second thickness may range between 20 nm to 30 nm.

At block 606, the first AlN layer is annealed at a temperature of 800 C or higher to form an annealed AlN layer. In various embodiments, the second AlN layer, on the device substrate, may remain unannealed.

At block 608, the carrier substrate is joined to the device substrate by bringing the two substrates together and fusing the annealed AlN layer to the second AlN layer of the device substrate. In some examples, this fusing may be performed by a fusion bonding process.

Advantages provided by the present embodiments for processing a bonded device are multifold. As a first advantage, the present approach, by splitting a bonding layer into two separate layers, arranged on a carrier substrate and on a device substrate, facilitates the independent treatment of the bonding layer on the carrier substrate, while not affecting the device substrate. A related second advantage is the ability to improve overall device properties, such as improved thermal conduction and leakage, by allocating a substantial portion of the bonding layer to the carrier substrate for thermal treatment that is not compatible with the device substrate.

The present disclosure is not to be limited in scope by the specific embodiments described herein. Indeed, other various embodiments and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose, yet those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method of forming a bonded device, comprising:
providing a carrier substrate;
forming, on a first surface of the carrier substrate, a first bonding layer for bonding to a device substrate; and
annealing the first bonding layer at a temperature of greater than 600° C.

2. The method of claim 1, further comprising:
providing a device substrate the device substrate comprising at least one semiconductor device; and
forming a second bonding layer on the device substrate,
bonding the carrier substrate to the device substrate via the first bonding layer and the second bonding layer.

3. The method of claim 2,
wherein the first bonding layer and the second bonding layer comprise AlN.

4. The method of claim 3,
wherein the first bonding layer is deposited on the carrier substrate by a physical vapor deposition at a temperature less than 600° C.

5. The method of claim 4,
wherein the first bonding layer is subject to an annealing after deposition at an annealing temperature of 800° C. or higher.

6. The method of claim 4, wherein the physical vapor deposition and the annealing are conducted in a common tool.

7. The method of claim 3,
wherein the second bonding layer is not subjected to deposition annealing that exceeds 600° C. before it is bonded to first bonding layer of the carrier substrate.

8. The method of claim 2, further comprising subjecting the carrier substrate and the device substrate to a fusion bonding process, wherein the first bonding layer is fused to the second bonding layer.

9. The method of claim 2, wherein the first bonding layer and the second bonding layer comprise one of: AlN, AlON, bilayers of AlN/AlO, AlN/SiO, hexagonal-BN, or crystalline diamond.

10. The method of claim 2, wherein the first bonding layer has a first thickness, and wherein the second bonding layer has a second thickness, less than the first thickness.

11. A bonded device, comprising:
a carrier substrate;
a device substrate; and
a first bonding layer at an inner surface of the carrier substrate; a second bonding layer at an inner surface of the device substrate, the second bonding layer bonded to the first bonding layer,
wherein the first bonding layer and the second bonding layer comprise a same material, and an average grain size of the first bonding layer is greater than an average grain size of the second bonding layer.

12. The bonded device of claim 11,
wherein the first bonding layer has a first thickness between 30 and 100 nm, and wherein the second bonding layer has a second thickness between 10 nm and 20 nm.

13. The bonded device of claim 11,
wherein the first bonding layer comprises a polycrystalline microstructure, having a first grain size, wherein the second bonding layer comprises a polycrystalline microstructure, having a second grain size, less than the first grain size.

14. The bonded device of claim 11, comprising a backside power delivery network architecture.

15. The bonded device of claim 11,
wherein the device substrate comprises a frontside region that is affixed to the second bonding layer, and
wherein the frontside region comprises an insulator material and a plurality of conductive structures, embedded in the insulator material.

16. The bonded device of claim 11,
wherein the first bonding layer and the second bonding layer comprise one of:
AlN, AlON, bilayers of AlN/AlO, AlN/SiO, hexagonal-BN, or crystalline diamond.

17. The bonded device of claim 11, comprising:
wherein the first bonding layer is a first AlN layer, having an upper surface that is affixed to the inner surface of the carrier substrate,
wherein the second bonding layer is a second AlN layer, affixed at an internal interface to the first bonding layer, and
wherein the device substrate comprises a backside power delivery network architecture.

18. The bonded device of claim 17,
wherein the first AlN layer comprises a polycrystalline microstructure, having a first grain size, and
wherein the second AlN layer comprises a polycrystalline microstructure, having a second grain size, less than the first grain size.

19. The bonded device of claim 17,
wherein the device substrate comprises a frontside region that is affixed to the second bonding layer, wherein the frontside region comprises an insulator material and a plurality of conductive structures, embedded in the insulator material.

20. The bonded device of claim 17,
wherein the first bonding layer comprises a first thickness, wherein the second bonding layer comprises a second thickness, less than the first thickness.
